(19) United States
(12) Patent Application Publication
(10) Pub. No.: US 2022/0399238 A1
(43) Pub. Date: Dec. 15, 2022

(54) APPARATUS AND METHOD FOR BONDING DETECTION, AND APPARATUS AND METHOD FOR THICKNESS AND UNIFORMITY DETECTION

(71) Applicant: CHONGQING KONKA PHOTOELECTRIC TECHNOLOGY RESEARCH INSTITUTE CO., LTD., Chongqing (CN)

(72) Inventors: Xun LI, Chongqing (CN); CHEN HUNG-WEN, Chongqing (CN); MING-TA TSAI, Chongqing (CN)

(21) Appl. No.: 17/881,000

(22) Filed: Aug. 4, 2022

Related U.S. Application Data
(63) Continuation of application No. PCT/CN2021/099430, filed on Jun. 10, 2021.

(51) Int. Cl. H01L 21/66; H01L 21/02

(52) U.S. Cl. CPC H01L 22/12; H01L 22/30; H01L 21/02623

(57) ABSTRACT

A method for bonding detection includes: disposing a liquid crystal component on one side of a growth substrate away from a light-emitting element; disposing a first electrode layer on one side of the liquid crystal component away from the growth substrate, and disposing a first polarizer on one side of the first electrode layer away from the liquid crystal component; disposing a second electrode layer on one side of a transient substrate away from an adhesive layer, and disposing a second polarizer on one side of the second electrode layer away from the transient substrate, polarization directions of the second polarizer and the first polarizer are orthogonal; irradiating the first polarizer with a uniform light; electrifying the first electrode layer and the second electrode layer; and detecting a uniformity and a thickness of the adhesive layer according to the light exited from one side of the second polarizer.

### CROSS-REFERENCE TO RELATED APPLICATION(S)

This application is a continuation of International Application No. PCT/CN2021/099430, filed Jun. 10, 2021, the disclosure of which is hereby incorporated by reference in its entirety.

### TECHNICAL FIELD

This disclosure relates to the technical field of light-emitting element manufacturing, and in particular, to an apparatus and method for bonding detection, and an apparatus and method for thickness and uniformity detection.

### BACKGROUND

At present, during mass transfer, for adjusting a distance between light-emitting elements on a growth substrate, improving a utilization efficiency of the light-emitting elements, or other requirements, the light-emitting elements formed on the growth substrate need to be transferred onto a transient substrate by a series of methods. Generally, an adhesive layer is formed on the transient substrate, and then the light-emitting elements are bonded with and fixed onto the adhesive layer on the transient substrate, so that the light-emitting elements are transferred onto the transient substrate from the growth substrate.

However, at present, after the growth substrate is bonded with the transient substrate, it is difficult to determine a uniformity of a thickness of the adhesive layer due to covering of the growth substrate and the transient substrate respectively on two sides of the adhesive layer. As a result, a bonding effect is unable to be determined.

Therefore, how to easily determine the uniformity of the thickness of the adhesive layer has become an urgent problem to-be-solved.

### SUMMARY

In a first aspect, a method for bonding detection is provided. The method for bonding detection is applicable to detect bonding of a growth substrate and a transient substrate, and a light-emitting element on the growth substrate is connected with an adhesive layer on the transient substrate. The method for bonding detection includes the following. A liquid crystal component is disposed on one side of the growth substrate away from the light-emitting element. A first electrode layer is disposed on one side of the liquid crystal component away from the growth substrate, and a first polarizer is disposed on one side of the first electrode layer away from the liquid crystal component. A second electrode layer is disposed on one side of the transient substrate away from the adhesive layer, and a second polarizer is disposed on one side of the second electrode layer away from the transient substrate, where the second polarizer has a polarization direction orthogonal to the first polarizer. The first polarizer is irradiated with a uniform light, where the light is exited in the polarization direction of the second polarizer. The first electrode layer and the second electrode layer are electrified to deflect a liquid crystal of the liquid crystal component. The light exited from one side of the second polarizer is received to detect a thickness and a uniformity of the adhesive layer.

In a second aspect, an apparatus for bonding detection is further provided. The apparatus for bonding detection is applicable to detect bonding of a growth substrate and a transient substrate, and a light-emitting element on the growth substrate is connected with an adhesive layer on the transient substrate. The apparatus for bonding detection includes a liquid crystal component, a first electrode layer, a first polarizer, a second electrode layer, and a second polarizer. The liquid crystal component is disposed on one side of the growth substrate away from the light-emitting element. The first electrode layer is disposed on one side of the liquid crystal component away from the growth substrate, and the first polarizer is disposed on one side of the first electrode layer away from the liquid crystal component. The second electrode layer is disposed on one side of the transient substrate away from the adhesive layer, and the second polarizer is disposed on one side of the second electrode layer away from the transient substrate, where the second polarizer has a polarization direction orthogonal to the first polarizer. The apparatus for bonding detection further includes a light source, a power supply, and a light detector. The light source is configured to irradiate the first polarizer with a uniform light, where the light is exited in the polarization direction of the second polarizer. The power supply is configured to electrify the first electrode layer and the second electrode layer to deflect a liquid crystal of the liquid crystal component. The light detector is configured to receive the light exited from one side of the second polarizer to detect a thickness and a uniformity of the adhesive layer.

In a third aspect, a method for thickness and uniformity detection is further provided. The method for thickness and uniformity detection includes the following. A liquid crystal component is disposed on one side of a portion which is to be detected. A first electrode layer is disposed on one side of the liquid crystal component away from the portion, and a first polarizer is disposed on one side of the first electrode layer away from the liquid crystal component. A second electrode layer is disposed on one side of the portion away from the liquid crystal component, and a second polarizer is disposed on one side of the second electrode layer away from the portion, where the second polarizer has a polarization direction orthogonal to the first polarizer. The first polarizer is irradiated with a uniform light, where the light is exited in the polarization direction of the second polarizer. The first electrode layer and the second electrode layer are electrified to deflect a liquid crystal of the liquid crystal component. The light exited from one side of the second polarizer is received to detect a thickness and a uniformity of the portion.

### BRIEF DESCRIPTION OF THE DRAWINGS

In order to describe technical solutions of implementations of the disclosure more clearly, the following will give a brief introduction to accompanying drawings required for describing the implementations. Apparently, the accompanying drawings hereinafter described are merely some implementations of the disclosure. Based on these accompanying drawings, those of ordinary skill in the art can also obtain other drawings without creative effort.

FIG. 1 is a flow chart illustrating a method for bonding detection according to an implementation.

FIG. 2 is a schematic structural diagram illustrating an operation of a method for bonding detection according to an implementation.

FIG. 3 is a schematic structural diagram illustrating an operation of a method for bonding detection according to an implementation.

FIG. 4 is a schematic structural diagram illustrating an operation of a method for bonding detection according to an implementation.

FIG. 5 is a schematic structural diagram illustrating an operation of a method for bonding detection according to an implementation.

FIG. 6 is a schematic structural diagram illustrating an operation of a method for bonding detection according to an implementation.

FIG. 7 is a schematic structural diagram illustrating an operation of a method for thickness and uniformity detection according to an implementation.

Description of reference signs of the accompanying drawings: 10—growth substrate, 20—light-emitting element, 21—epitaxial structure, 22—P electrode, 23—N electrode, 30—transient substrate, 40—adhesive layer, 45—variant portion, 51—first electrode layer, 52—second electrode layer, 60—auxillary substrate, 70—liquid crystal component, 71—first alignment film, 72—second alignment film, 73—liquid crystal, 91—first polarizer, 92—second polarizer, 100—portion 100 to-be-detected.

### DETAILED DESCRIPTION

In order to facilitate understanding of the disclosure, a detailed description will now be given with reference to relevant accompanying drawings. The accompanying drawings illustrate some examples of implementations of the disclosure. However, the disclosure can be implemented in many different forms and is not limited to the implementations described herein. On the contrary, these implementations are provided for a more thorough and comprehensive understanding of the disclosure.

Unless otherwise defined, all technical and scientific terms used herein have the same meaning as commonly understood by those skilled in the art of the disclosure. The terms used herein in the disclosure are for the purpose of describing implementations only and are not intended to limit the disclosure.

At present, during mass transfer, for adjusting a distance between light-emitting elements on a growth substrate, improving a utilization efficiency of the light-emitting elements, or other requirements, the light-emitting elements formed on the growth substrate need to be transferred onto a transient substrate by a series of methods. Generally, an adhesive layer is formed on the transient substrate, and then the light-emitting elements are bonded with and fixed onto the adhesive layer on the transient substrate, so that the light-emitting elements are transferred onto the transient substrate from the growth substrate.

However, at present, after the growth substrate is bonded with the transient substrate, it is difficult to determine a uniformity of a thickness of the adhesive layer due to covering of the growth substrate and the transient substrate respectively on two sides of the adhesive layer. As a result, a bonding effect is unable to be determined.

Therefore, how to easily determine the uniformity of the thickness of the adhesive layer has become an urgent problem to-be-solved.

Based on the above, a solution capable of solving the above technical problem is provided in the disclosure, which will be explained in details in the following implementations.

A method for bonding detection is provided. The method for bonding detection is applicable to detect bonding of a growth substrate and a transient substrate, and a light-emitting element on the growth substrate is connected with an adhesive layer on the transient substrate. The method for bonding detection includes the following. A liquid crystal component is disposed on one side of the growth substrate away from the light-emitting element. A first electrode layer is disposed on one side of the liquid crystal component away from the growth substrate, and a first polarizer is disposed on one side of the first electrode layer away from the liquid crystal component. A second electrode layer is disposed on one side of the transient substrate away from the adhesive layer, and a second polarizer is disposed on one side of the second electrode layer away from the transient substrate, where the second polarizer has a polarization direction orthogonal to the first polarizer. The first polarizer is irradiated with a uniform light, where the light is exited in the polarization direction of the second polarizer. The first electrode layer and the second electrode layer are electrified to deflect a liquid crystal of the liquid crystal component. The light exited from one side of the second polarizer is received to detect a thickness and a uniformity of the adhesive layer.

According to the method for bonding detection of the disclosure, structures of the liquid crystal component, the first electrode layer, the second electrode layer, the first polarizer, and the second polarizer are provided. By electrifying the first electrode layer and the second electrode layer, a polarized light passing through the first polarizer is exited from the second polarizer under action of deflection of the liquid crystal of the liquid crystal component. Since a voltage distribution is affected by structures between the first electrode layer and the second electrode layer, different deflection of the liquid crystal of the liquid crystal component may occur, and thus the light exited has different transmittances and different light intensities. When the adhesive layer has a uniform film thickness, the light exited has regular light intensities; conversely, when the adhesive layer has a non-uniform film thickness, the light exited has a sudden-change light intensity(s) besides regular light intensities. It should be noted that, the “sudden-change light intensity” of the disclosure refers to a light intensity that changes not following the whole light-intensity distribution rule. Based on this, a uniformity of the film thickness of the adhesive layer can be determined, and a location where the film thickness of the adhesive layer is not uniform can be positioned. The method for bonding detection is simple in design idea and easy to operate, and can be used to determine an effect of the bonding between the growth substrate and the transient substrate.

In an implementation, the method for bonding detection further includes disposing the first electrode layer and the first polarizer on two opposite surfaces of an auxiliary substrate. The auxiliary substrate is provided to provide a good support, which can increase a structural intensity, so that the first electrode layer, the first polarizer, and the liquid crystal component have sufficient stability and reliability.

In an implementation, the liquid crystal component includes a first alignment film, a second alignment film, and the liquid crystal, where the first alignment film is connected with the first electrode layer, the second alignment film is connected with the growth substrate, and the liquid crystal is disposed between the first alignment film and the second alignment film. Structures of the first alignment film, the second alignment film, and the liquid crystal are provided, so that a polarization direction of the polarized light can be adjusted, to select and filter a light passing through the liquid crystal component, which will not affect passing of normal lights while avoiding interference of external stray lights.

In an implementation, the liquid crystal has a thickness ranging from 2 μm to 4 μm. Such thickness of the liquid crystal is set, which can satisfy requirements for light selection and filtering of the liquid crystal component.

In an implementation, the first electrode layer and the second electrode layer electrified have opposite electrical polarities.

In an implementation, the method for bonding detection further includes the following. A database of a correspondence between thicknesses of the adhesive layer and light-exiting intensities is established by measuring a light-exiting intensity when the adhesive layer has a preset thickness. The thickness of the adhesive layer is detected as follows. A light-exiting intensity of the light exited is measured. Searched for the thickness of the adhesive layer in the database according to the light-exiting intensity of the light exited.

In an implementation, the uniformity of the adhesive layer is detected as follows. The light exited is measured to obtain a whole light-intensity distribution. Search for a sudden-change light intensity in the whole light-intensity distribution. The uniformity of the adhesive layer is determined based on the sudden-change light intensity searched.

Based on the same inventive concept, the disclosure further provides a method for mass transfer. The method for mass transfer includes the above method for bonding detection.

According to the method for bonding detection of the disclosure, by electrifying the first electrode layer and the second electrode layer, a polarized light passing through the first polarizer is exited from the second polarizer under action of deflection of the liquid crystal of the liquid crystal component. Since a voltage distribution is affected by structures between the first electrode layer and the second electrode layer, different deflection of the liquid crystal of the liquid crystal component may occur, and thus the light exited has different transmittances and different light intensities. When the adhesive layer has a uniform film thickness, the light exited has regular light intensities; conversely, when the adhesive layer has a non-uniform film thickness, the light exited has a sudden-change light intensity(s) besides regular light intensities. Based on this, a uniformity of the film thickness of the adhesive layer can be determined, and a location where the film thickness of the adhesive layer is not uniform can be positioned. The method for bonding detection is simple in design idea and easy to operate, and can be used to determine an effect of the bonding between the growth substrate and the transient substrate.

Based on the same inventive concept, the disclosure further provides an apparatus for bonding detection. The apparatus for bonding detection is applicable to detect bonding of a growth substrate and a transient substrate, and a light-emitting element on the growth substrate is connected with an adhesive layer on the transient substrate. The apparatus for bonding detection includes a liquid crystal component, a first electrode layer, a first polarizer, a second electrode layer, and a second polarizer. The liquid crystal component is disposed on one side of the growth substrate away from the light-emitting element. The first electrode layer is disposed on one side of the liquid crystal component away from the growth substrate, and the first polarizer is disposed on one side of the first electrode layer away from the liquid crystal component. The second electrode layer is disposed on one side of the transient substrate away from the adhesive layer, and the second polarizer is disposed on one side of the second electrode layer away from the transient substrate, where the second polarizer has a polarization direction orthogonal to the first polarizer. The apparatus for bonding detection further includes a light source, a power supply, and a light detector. The light source is configured to irradiate the first polarizer with a uniform light, where the light is exited in the polarization direction of the second polarizer. The power supply is configured to electrify the first electrode layer and the second electrode layer to deflect a liquid crystal of the liquid crystal component. The light detector is configured to receive the light exited from one side of the second polarizer to detect a thickness and a uniformity of the adhesive layer.

By electrifying the first electrode layer and the second electrode layer, a polarized light passing through the first polarizer is exited from the second polarizer under action of deflection of the liquid crystal of the liquid crystal component. Since a voltage distribution is affected by structures between the first electrode layer and the second electrode layer, different deflection of the liquid crystal of the liquid crystal component may occur, and thus the light exited has different transmittances and different light intensities. When the adhesive layer has a uniform film thickness, the light exited has regular light intensities; conversely, when the adhesive layer has a non-uniform film thickness, the light exited has a sudden-change light intensity(s) besides regular light intensities. Based on this, a uniformity of the film thickness of the adhesive layer can be determined, and a location where the film thickness of the adhesive layer is not uniform can be positioned. The method for bonding detection is simple in design idea and easy to operate, and can be used to determine an effect of the bonding between the growth substrate and the transient substrate.

In an implementation, the apparatus for bonding detection further includes an auxiliary substrate, where the first electrode layer and the first polarizer are disposed on two opposite surfaces of the auxiliary substrate. The auxiliary substrate is provided to provide a good support, which can increase a structural intensity, so that the first electrode layer, the first polarizer, and the liquid crystal component have sufficient stability and reliability.

In an implementation, the liquid crystal component includes a first alignment film, a second alignment film, and the liquid crystal, where the first alignment film is connected with the first electrode layer, the second alignment film is connected with the growth substrate, and the liquid crystal is disposed between the first alignment film and the second alignment film. Structures of the first alignment film, the second alignment film, and the liquid crystal are provided, so that a polarization direction of the polarized light can be adjusted, to select and filter a light passing through the liquid crystal component, which will not affect passing of normal lights while avoiding interference of external stray lights.

In an implementation, the liquid crystal has a thickness ranging from 2 μm to 4 μm. Such thickness of the liquid crystal is set, which can satisfy requirements for light selection and filtering of the liquid crystal component.

In an implementation, the first electrode layer and the second electrode layer electrified by the power supply have opposite electrical polarities.

In an implementation, the light detector is further configured to: measure a light-exiting intensity of the light exited, establish a database of a correspondence between thicknesses of the adhesive layer and light-exiting intensities by measuring a light-exiting intensity when the adhesive layer has a preset thickness, and search for the thickness of the adhesive layer in the database according to the light-exiting intensity of the light exited measured by the light detector.

In an implementation, the light detector is further configured to: measure the light exited to obtain a whole light-intensity distribution; search for a sudden-change light intensity in the whole light-intensity distribution; and determine the uniformity of the adhesive layer based on the sudden-change light intensity searched.

Based on the same inventive concept, the disclosure further provides a method for thickness and uniformity detection. The method for thickness and uniformity detection includes the following. A liquid crystal component is disposed on one side of a portion which is to be detected. A first electrode layer is disposed on one side of the liquid crystal component away from the portion, and a first polarizer is disposed on one side of the first electrode layer away from the liquid crystal component. A second electrode layer is disposed on one side of the portion away from the liquid crystal component, and a second polarizer is disposed on one side of the second electrode layer away from the portion, where the second polarizer has a polarization direction orthogonal to the first polarizer. The first polarizer is irradiated with a uniform light, where the light is exited in the polarization direction of the second polarizer. The first electrode layer and the second electrode layer are electrified to deflect a liquid crystal of the liquid crystal component. The light exited from one side of the second polarizer is received to detect a thickness and a uniformity of the portion.

In an implementation, the method for thickness and uniformity detection further includes the following. A database of a correspondence between thicknesses of the portion and light-exiting intensities is established by measuring a light-exiting intensity when the portion has a preset thickness. The thickness of the portion is detected as follows. A light-exiting intensity of the light exited is measured. Search for the thickness of the portion in the database according to the light-exiting intensity of the light exited.

In an implementation, the uniformity of the portion is detected as follows. The light exited is measured to obtain a whole light-intensity distribution. Search for a sudden-change light intensity in the whole light-intensity distribution. The uniformity of the portion is determined based on the sudden-change light intensity searched.

In an implementation, the liquid crystal has a thickness ranging from 2 μm to 4 μm.

In an implementation, the first electrode layer and the second electrode layer electrified have opposite electrical polarities.

In an implementation, the liquid crystal component comprises a first alignment film, a second alignment film, and the liquid crystal, wherein the first alignment film is connected with the first electrode layer, the second alignment film is connected with the portion, and the liquid crystal is disposed between the first alignment film and the second alignment film.

By electrifying the first electrode layer and the second electrode layer, a polarized light passing through the first polarizer is exited from the second polarizer under action of deflection of the liquid crystal of the liquid crystal component. Since a voltage distribution is affected by structures between the first electrode layer and the second electrode layer, different deflection of the liquid crystal of the liquid crystal component may occur, and thus the light exited has different transmittances and different light intensities. When the portion to-be-detected has a uniform film thickness, the light exited has regular light intensities; conversely, when the portion to-be-detected has a non-uniform film thickness, the light exited has a sudden-change light intensity(s) besides regular light intensities. Based on this, a uniformity of the film thickness of the portion to-be-detected can be determined, and a location where the film thickness of the portion to-be-detected is not uniform can be positioned. The method for thickness and uniformity detection is simple in design idea and easy to operate.

Based on the same inventive concept, the disclosure further provides an apparatus for thickness and uniformity detection. The apparatus for thickness and uniformity detection includes a liquid crystal component, a first electrode layer, a first polarizer, a second electrode layer, and a second polarizer. The liquid crystal component is disposed on one side of a portion which is to be detected. The first electrode layer is disposed on one side of the liquid crystal component away from the portion, and the first polarizer is disposed on one side of the first electrode layer away from the liquid crystal component. The second electrode layer is disposed on one side of the portion away from the liquid crystal component, and the second polarizer is disposed on one side of the second electrode layer away from the portion, where the second polarizer has a polarization direction orthogonal to the first polarizer. The apparatus for thickness and uniformity detection further includes a light source, a power supply, and a light detector. The light source is configured to irradiate the first polarizer with a uniform light, where the light is exited in the polarization direction of the second polarizer. The power supply is configured to electrify the first electrode layer and the second electrode layer to deflect a liquid crystal of the liquid crystal component. The light detector is configured to receive the light exited from one side of the second polarizer to detect a thickness and a uniformity of the portion.

By electrifying the first electrode layer and the second electrode layer, a polarized light passing through the first polarizer is exited from the second polarizer under action of deflection of the liquid crystal of the liquid crystal component. Since a voltage distribution is affected by structures between the first electrode layer and the second electrode layer, different deflection of the liquid crystal of the liquid crystal component may occur, and thus the light exited has different transmittances and different light intensities. When the portion to-be-detected has a uniform film thickness, the light exited has regular light intensities; conversely, when the portion to-be-detected has a non-uniform film thickness, the light exited has a sudden-change light intensity(s) besides regular light intensities. Based on this, a uniformity of the film thickness of the portion to-be-detected can be determined, and a location where the film thickness of the portion to-be-detected is not uniform can be positioned. The method for thickness and uniformity detection is simple in design idea and easy to operate.

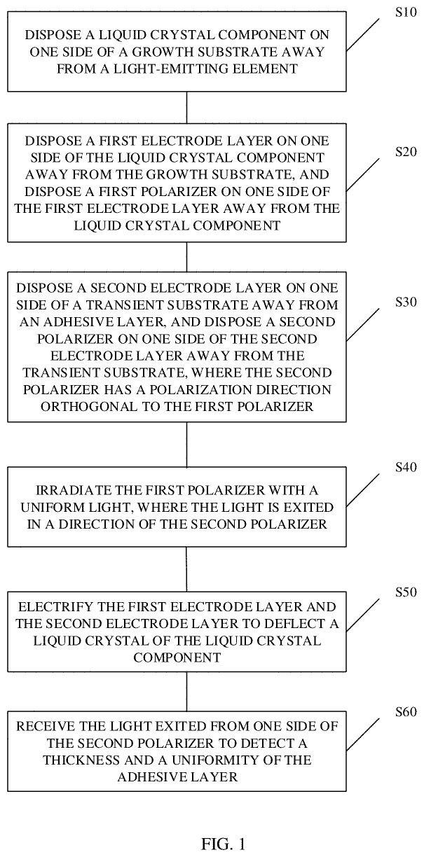

A method for bonding detection is provided in implementations of the disclosure. Referring to FIG. 1 to FIG. 6, the method for bonding detection is applicable to detect bonding of a growth substrate 10 and a transient substrate 30, and a light-emitting element 20 on the growth substrate 10 is connected with an adhesive layer 40 on the transient substrate 30. Specifically, the method for bonding detection is applicable to detect a uniformity of a thickness of the adhesive layer 40 between the growth substrate 10 and the transient substrate 30 which are bonded.

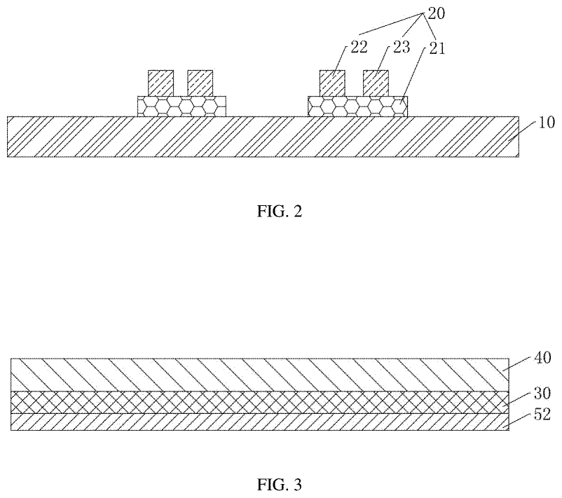

A process of mass transfer includes growth, transfer, bonding of the light-emitting element 20, etc. Referring to FIG. 2, the light-emitting element 20 is grown on the growth substrate 10, where the growth substrate 10 may be made of sapphire, etc., and the light-emitting element 20 may be a micro-light-emitting diode (micro-LED). Specifically, the light-emitting element 20 may include an epitaxial structure 21, a P electrode 22, and an N electrode 23, where the epitaxial structure 21 is formed on the growth substrate 10, and the P electrode 22 and the N electrode 23 are formed on the epitaxial structure 21. There may be multiple light-emitting elements 20, and the multiple light-emitting elements 20 are spaced apart. Optionally, the light-emitting element 20 includes a red light-emitting element 20, a green light-emitting element 20, and a blue light-emitting element 20. Optionally, light-emitting elements 20 with an identical type can be grown on one growth substrate 10; alternatively, the red light-emitting element 20, the green light-emitting element 20, and the blue light-emitting element 20 are grown respectively on three growth substrates 10. Optionally, light-emitting elements 20 with various types can be grown on one growth substrate 10. For example, the red light-emitting element 20, the green light-emitting element 20, and the blue light-emitting element 20 are grown on one growth substrate 10.

Referring to FIG. 3, the adhesive layer 40 is formed on the transient substrate 30, where the transient substrate 30 may be made of glass, sapphire, or other materials, and the adhesive layer 40 may be made of pyrolytic adhesive. The transient substrate 30 is used to transfer the light-emitting element 20 grown on the growth substrate 10.

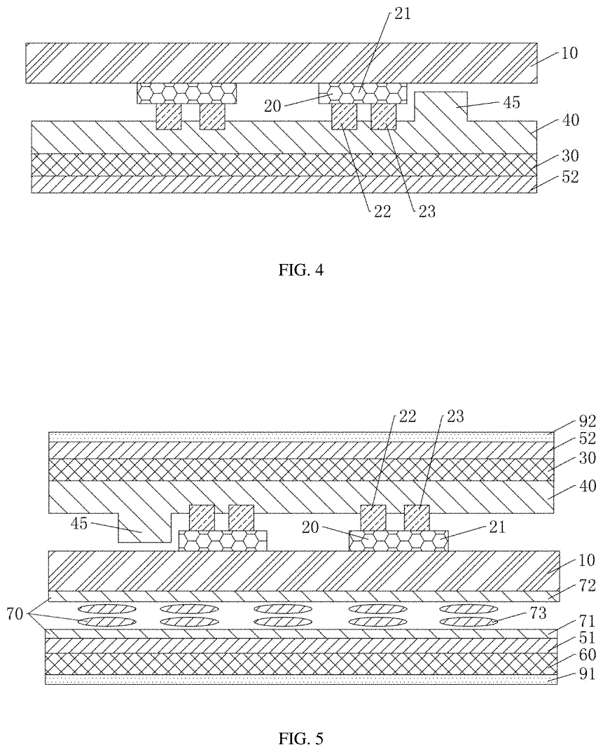

Referring to FIG. 4, the growth substrate 10 is bonded with the transient substrate 30, and the light-emitting element 20 on the growth substrate 10 is connected with the adhesive layer 40 on the transient substrate 30. Specifically, the P electrode 22 and the N electrode 23 of the light-emitting element 20 are cemented with the adhesive layer 40. Extrusion during bonding may cause a non-uniform thickness of part of the adhesive layer 40. As illustrated in FIG. 4, a variant portion 45 (e.g., a local protrusion) is formed due to extrusion on the adhesive layer 40, where the variant portion 45 has a thickness different from other parts of the adhesive layer 40. It should be understood that, the thickness herein refers to a size in a direction perpendicular to a surface, where the adhesive layer 40 is formed, of the transient substrate 30, which is stated herein and will not be repeated in the following. The variant portion 45 may be convex or concave compared with the other parts of the adhesive layer 40, and the variant portion 45 may be embodied as multiple variant portions. The multiple variant portions 45 may have an identical shape or different shapes, which is not specifically limited herein.

In view of the above phenomenon of the non-uniform thickness of the adhesive layer 40 during the bonding of the growth substrate 10 and the transient substrate 30, the disclosure provides a solution which can easily detect a uniformity of the thickness of the adhesive layer 40.

Referring to FIG. 1, a method for bonding detection of implementations of the disclosure includes operations at S10 to S60, which will be illustrated in detail below.

At S10, a liquid crystal component 70 is disposed on one side of the growth substrate 10 away from the light-emitting element 20.

Referring to FIG. 5, the operation of disposing the liquid crystal component 70 may be performed before or after the growth substrate 10 is bonded with the transient substrate 30. The liquid crystal component 70 may be a structure that can be installed and used independently, and may be connected with the growth substrate 10 through splicing or other manners. The liquid crystal component 70 is disposed, which can deflect a polarized light, facilitating detection of the light.

Optionally, the liquid crystal component includes a first alignment film 71, a second alignment film 72, and the liquid crystal 73, where the first alignment film 71 is opposite to the second alignment film 72, the second alignment film 72 is connected with the growth substrate 10, and the liquid crystal 73 is disposed between the first alignment film 71 and the second alignment film 72. The first alignment film 71 and the second alignment film 72 each may be made of polyimide and are used to arrange the liquid crystal 73 in order. The first alignment film 71 and the second alignment film 72 each may be an independent structure or may be formed on a carrier such as a glass plate. The liquid crystal 73 includes multiple particles in a liquid crystal state, and deflection of the multiple particles may occur under action of a voltage to change a polarization direction of the polarized light passing through the liquid crystal 73. Structures of the first alignment film 71, the second alignment film 72, and the liquid crystal 73 are provided, so that the polarization direction of the polarized light can be adjusted, to select and filter a light passing through the liquid crystal component 70, which will not affect passing of normal lights while avoiding interference of external stray lights.

Optionally, the liquid crystal 73 has a thickness ranging from 2 μm to 4 μm. Specifically, the thickness of the liquid crystal 73 may be 2 μm, 3 μm, 4 μm, etc. Such thickness of the liquid crystal 73 is set, which can satisfy requirements for light selection and filtering of the liquid crystal component 70.

At S20, a first electrode layer 51 is disposed on one side of the liquid crystal component 70 away from the growth substrate 10, and a first polarizer 91 is disposed on one side of the first electrode layer 51 away from the liquid crystal component 70.

Referring to FIG. 5, the operation of disposing the first electrode layer 51 may also be performed before or after the growth substrate 10 is bonded with the transient substrate 30, and the first electrode layer 51 is connected with the first alignment film 71 of the liquid crystal component 70. The first electrode layer 51 may be made of indium tin oxide (ITO), and can be formed on a carrier such as a glass plate to form a conductive structure. The first polarizer 91 can allow a light of a first polarization direction to pass through and block a light of other directions, where the light of the first polarization direction may be an S polarized light or a P polarized light.

Optionally, the first electrode layer 51 and the first polarizer 91 are disposed on two opposite surfaces of an auxiliary substrate 60. During manufacturing, the auxiliary substrate 60 may be provided first, the first electrode layer 51 and the first polarizer 91 are formed on the auxiliary substrate 60, and then the auxiliary substrate 60 and the first electrode layer 51 are connected with the liquid crystal component 70. The liquid crystal component 70 may be connected with the first electrode layer 51 and then connected with the growth substrate 10, or the liquid crystal component 70 may be connected with the growth substrate 10 and then connected with the first electrode layer 51. The auxiliary substrate 60 is provided to provide a good support, which can increase a structural intensity, so that the first electrode layer 51, the first polarizer 91, and the liquid crystal component 70 have sufficient stability and reliability.

At S30, a second electrode layer 52 is disposed on one side of the transient substrate 30 away from the adhesive layer 40, and a second polarizer 92 is disposed on one side of the second electrode layer 52 away from the transient substrate 30, where the second polarizer 92 has a polarization direction orthogonal to the first polarizer 91.

Referring to FIG. 3 to FIG. 5, the operation of disposing the second electrode layer 52 may also be performed before or after the growth substrate 10 is bonded with the transient substrate 30, and the second electrode layer 52 may be connected with the transient substrate 30 and the second polarizer 92. The second electrode layer 52 may also be made of ITO, and can be formed on a carrier such as a glass plate to form a conductive structure. The second polarizer 92 can allow a light of a second polarization direction to pass through and filter a light of other non-second polarization directions, where the light of the second polarization direction may be an S polarized light or a P polarized light. It should be understood that, since the first polarization direction is orthogonal to the second polarization direction, the light of the second polarization direction is a P polarized light when the light of the first polarization direction is an S polarized light, or the light of the second polarization direction is an S polarized light when the light of the first polarization direction is a P polarized light. A light of a certain polarization direction passing through the first polarizer 91 cannot pass through the second polarizer 92, and the liquid crystal component 70, however, can change a polarization direction of a polarized light, such that a light passing through the first polarizer 91 can also pass through the second polarizer 92.

At S40, the first polarizer 91 is irradiated with a uniform light, where the light is exited in a direction of the second polarizer 92.

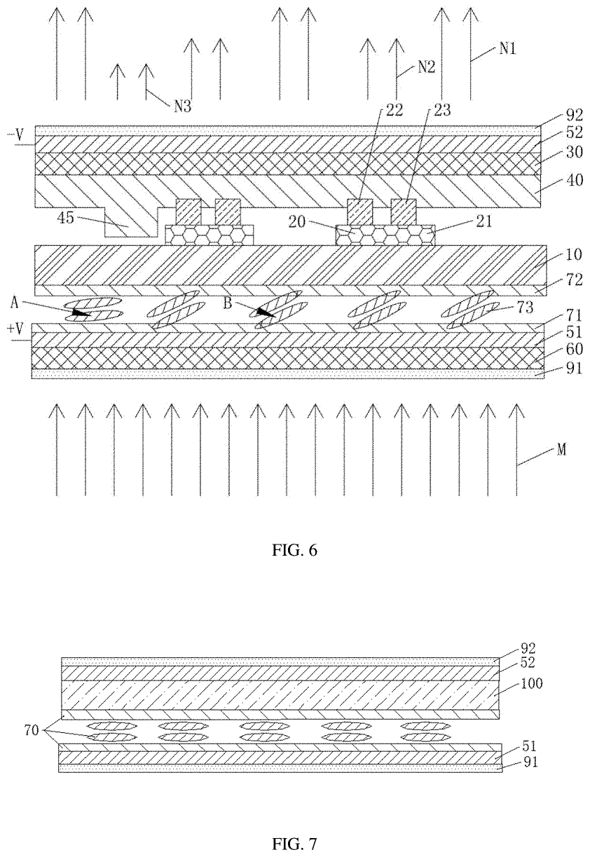

Referring to FIG. 6, a light can be provided by a light source such as an LED, and a structure such as a light equalization plate may also be provided, where a light emitted by the light source irradiates the first polarizer 91 after light equalization through the light equalization plate, as illustrated in M in FIG. 6.

At S50, the first electrode layer 51 and the second electrode layer 52 are electrified to deflect a liquid crystal 73 of the liquid crystal component 70.

Referring to FIG. 6, the first electrode layer 51 and the second electrode layer 52 are electrified by a power supply, and the first electrode layer 51 and the second electrode layer 52 electrified have opposite electrical polarities. For example, positive voltage +V is applied to the first electrode layer 51 while negative voltage −V is applied to the second electrode layer 52. Alternatively, negative voltage −V is applied to the first electrode layer 51 while positive voltage +V is applied to the second electrode layer 52. The applied voltages have the same magnitude and opposite polarities. A voltage between the first electrode layer 51 and the second electrode layer 52 may be distributed among structures between the first electrode layer 51 and the second electrode layer 52. Specifically, the voltage may be distributed among the first alignment film 71, the second alignment film 72, the liquid crystal 73, the growth substrate 10, the light-emitting element 20, the adhesive layer 40, and the transient substrate 30. The liquid crystal 73 is deflected under drive of a voltage distributed on the liquid crystal 73, such that a light passing through the first polarizer 91 can change from linear polarization to elliptical polarization under action of the liquid crystal 73 and can partially pass through the second polarizer 92.

Since the variant portion 45 of the adhesive layer 40 has a thickness different from the other parts of the adhesive layer 40, a resistance of the variant portion 45 is different from that of the other parts, such that a divided voltage of the variant portion 45 is different from that of the other parts, and a voltage applied to the liquid crystal 73 corresponding to the variant portion 45 is different from voltages applied to the liquid crystal 73 corresponding to the other parts. As illustrated in FIG. 6, the liquid crystal 73 at A corresponds to the variant portion 45, and the liquid crystal 73 at B corresponds to the other parts of the adhesive layer 40. A degree of deflection of the liquid crystal 73 at A corresponding to the variant portion 45 is different from a degree of deflection of the liquid crystal 73 at B corresponding to the other parts of the adhesive layer 40 due to different voltages, such that a transmittance of a light at A is different from that of a light at B. Based on the principle, since structures of the growth substrate 10, the transient substrate 30, and the light-emitting element are controllable, stable, and not easily deformed, and other factors resulting in different transmittances of a light can be excluded, it is possible to focus on different film thicknesses of the adhesive layer 40 resulting in different transmittances of the light, thereby realizing detection of a non-uniform film thickness of the adhesive layer 40.

At S60, the light exited from one side of the second polarizer 92 is received to detect a thickness and a uniformity of the adhesive layer 40.

Referring to FIG. 6, the light exited can be detected by a light detector. The light detector may be a light sensor, a camera, etc. A transmittance of the liquid crystal 73 varies with a thickness of the adhesive layer 40. In addition, since multiple light-emitting elements 20 are provided, a transmittance of a light at a location disposed with the light-emitting element 20 is different from a transmittance of a light at a location disposed with no light-emitting element 20. A light intensity at a location with a relatively high light transmittance is relatively strong, and a light intensity at a location with a relatively low light transmittance is relatively weak. Light intensities of lights detected in respective areas can be compared when detecting a uniformity of the light exited from one side of the second polarizer 92, which can qualitatively determine which locations have a relatively strong light intensity and which locations have a relatively weak light intensity, such that a location having a relatively weak light intensity may be determined as a location where a film thickness of the adhesive layer 40 is not uniform.

Since a voltage distributed onto the liquid crystal 73 is affected by structures between the first electrode layer 51 and the second electrode layer 52, as illustrated in FIG. 6, structures of the growth substrate 10 and the transient substrate 30 are unchanged and multiple light-emitting elements 20 are arranged regularly, if the adhesive layer 40 has a uniform film thickness, when detecting the uniformity of the light, a light intensity at a location (e.g., N1) with no light-emitting element 20 should be the strongest, and a light intensity at a location (e.g., N2) with the light-emitting element 20 should be relatively weak, where the light intensity at N1 is stronger than the light intensity at N2, and the whole light-intensity distribution should be regular. Conversely, if the adhesive layer 40 has a non-uniform film thickness, a light intensity at a location (e.g., N3) corresponding to the variant portion 45 is stronger or weaker than a light intensity at a location with no light-emitting element 20 and corresponding to a uniform film thickness. The light intensity at N3 is stronger than the light intensity at N1 if the variant portion 45 has a thickness less than the other parts, and the light intensity at N3 is weaker than the light intensity at N1 if the variant portion 45 has a thickness greater than the other parts. The light intensity at the location corresponding to the variant portion 45 may also be the same as, stronger than, or weaker than the light intensity at the location with the light-emitting element 20, that is, the light intensity at N3 may be the same as, stronger than, or weaker than the light intensity at N2. In either case, a sudden-change light intensity exists besides the whole light-intensity distribution is regular. Therefore, a location where the film thickness is not uniform can be positioned by searching for a location having a sudden-change light intensity, thereby realizing detection of a uniformity of the film thickness of the adhesive layer 40.

According to the method for bonding detection of the disclosure, structures of the liquid crystal component 70, the first electrode layer 51, the second electrode layer 52, the first polarizer 91, and the second polarizer 92 are provided. By electrifying the first electrode layer 51 and the second electrode layer 52, a polarized light passing through the first polarizer 91 is exited from the second polarizer 92 under action of deflection of the liquid crystal 73 of the liquid crystal component 70. Since a voltage distribution is affected by structures between the first electrode layer 51 and the second electrode layer 52, different deflection of the liquid crystal 73 of the liquid crystal component 70 may occur, and thus the light exited has different transmittances and different light intensities. When the adhesive layer 40 has a uniform film thickness, the light exited has a regular light intensity; conversely, when the adhesive layer 40 has a non-uniform film thickness, the light exited has a sudden-change light intensity(s) besides regular light intensities. Based on this, a uniformity of the film thickness of the adhesive layer 40 can be determined, and a location where the film thickness of the adhesive layer 40 is not uniform can be positioned. The method for bonding detection is simple in design idea and easy to operate, and can be used to determine an effect of the bonding between the growth substrate 10 and the transient substrate 30.

In an implementation, the method for bonding detection further includes the following. Uniformity detection is performed on the light exited, and a light-exiting intensity of the light exited is measured. A database of a correspondence between thicknesses of the adhesive layer 40 and light-exiting intensities of the light is established by measuring a light-exiting intensity when the adhesive layer 40 has a preset thickness. The thickness of the adhesive layer 40 is searched in the database according to the light-exiting intensity of the light exited.

The light detector can measure the light-exiting intensity of the light. In a case that the growth substrate 10, the transient substrate 30, and the light-emitting element 20 are unchanged, the film thickness of the adhesive layer 40 is a unique factor resulting in a change in the light-exiting intensity, and therefore, a list of a correspondence between a set of thicknesses of the adhesive layer 40 and light-exiting intensities can be obtained by measuring light-exiting intensities when the adhesive layer 40 has a set of known thicknesses (i.e., preset thicknesses). When the number of measured different film thicknesses of the adhesive layer 40 is large enough, a database can be obtained. Subsequently, the film thickness of the adhesive layer 40 can be obtained quantitatively in the database by merely measuring the light-exiting intensity, such that a process of mass transfer can be more precisely controlled, thereby improving a quality.

Referring to FIG. 1 to FIG. 6, implementations of the disclosure further provide a method for mass transfer. The method for mass transfer includes the above method for bonding detection in the foregoing implementations.

The method for mass transfer mainly includes: connecting the light-emitting element 20 on the growth substrate 10 with the adhesive layer 40 on the transient substrate 30, stripping off the growth substrate 10, transferring the light-emitting element 20 on the transient substrate 30 onto a circuit backplane, stripping off the transient substrate 30, etc.

As illustrated in FIG. 2 to FIG. 6, when transferring the light-emitting element 20 on the growth substrate 10 onto the transient substrate 30, after the light-emitting element 20 is connected with the adhesive layer 40, the method for bonding detection of the foregoing implementations is performed to determine a uniformity of the film thickness of the adhesive layer 40, and then the liquid crystal component 70, the first electrode layer 51, the auxiliary substrate 60, and the first polarizer 91 each on the growth substrate 10 and the growth substrate 10 are stripped off through laser lift off (LLO). After the light-emitting element 20 on the transient substrate 30 is transferred onto the circuit backplane, the second electrode layer 52 and the second polarizer 92 each on the transient substrate 30 and the transient substrate 30 are stripped off through mechanical strip off. Therefore, in the method for mass transfer of the implementations, the operations of the method for bonding detection will not affect the overall operations of the method for mass transfer.

According to the method for mass transfer of the implementation, by adopting the method for bonding detection of the disclosure, by electrifying the first electrode layer 51 and the second electrode layer 52, a polarized light passing through the first polarizer 91 is exited from the second polarizer 92 under action of deflection of the liquid crystal 73 of the liquid crystal component 70. Since a voltage distribution is affected by structures between the first electrode layer 51 and the second electrode layer 52, different deflection of the liquid crystal 73 of the liquid crystal component 70 may occur, and thus the light exited has different transmittances and different light intensities. When the adhesive layer 40 has a uniform film thickness, the light exited has regular light intensities, conversely, when the adhesive layer 40 has a non-uniform film thickness, the light exited has a sudden-change light intensity(s) besides regular light intensities. Based on this, a uniformity of the film thickness of the adhesive layer 40 can be determined and a location where the film thickness of the adhesive layer 40 is not uniform can be positioned. The method for bonding detection is simple in design idea and easy to operate, and can be used to determine an effect of the bonding between the growth substrate 10 and the transient substrate 30.

Based on the same inventive concept, referring to FIG. 2 to FIG. 6, implementations of the disclosure further provide an apparatus for bonding detection. The apparatus for bonding detection is applicable to detect bonding of a growth substrate 10 and a transient substrate 30, and a light-emitting element 20 on the growth substrate 10 is connected with an adhesive layer 40 on the transient substrate 30.

The apparatus for bonding detection includes a liquid crystal component 70, a first electrode layer 51, a first polarizer 91, a second electrode layer 52, and a second polarizer 92. The liquid crystal component 70 is disposed on one side of the growth substrate 10 away from the light-emitting element 20. The first electrode layer 51 is disposed on one side of the liquid crystal component 70 away from the growth substrate 10, and the first polarizer 91 is disposed on one side of the first electrode layer 51 away from the liquid crystal component 70. The second electrode layer 52 is disposed on one side of the transient substrate 30 away from the adhesive layer 40, and the second polarizer 92 is disposed on one side of the second electrode layer 52 away from the transient substrate 30, where the second polarizer 92 has a polarization direction orthogonal to the first polarizer 91.

The apparatus for bonding detection further includes a light source, a power supply, and a light detector. The light source is configured to irradiate the first polarizer 91 with a uniform light, where the light is exited in a direction of the second polarizer 92. The power supply is configured to electrify the first electrode layer 51 and the second electrode layer 52 to deflect a liquid crystal 73 of the liquid crystal component 70. The light detector is configured to receive the light exited from one side of the second polarizer 92 to detect a thickness and a uniformity of the adhesive layer 40.

According to the apparatus for bonding detection of the implementation, by electrifying the first electrode layer 51 and the second electrode layer 52, a polarized light passing through the first polarizer 91 is exited from the second polarizer 92 under action of deflection of the liquid crystal 73 of the liquid crystal component 70. Since a voltage distribution is affected by structures between the first electrode layer 51 and the second electrode layer 52, different deflection of the liquid crystal 73 of the liquid crystal component 70 may occur, and thus the light exited has different transmittances and different light intensities. When the adhesive layer 40 has a uniform film thickness, the light exited has regular light intensities; conversely, when the adhesive layer 40 has a non-uniform film thickness, the light exited has a sudden-change light intensity(s) besides regular light intensities. Based on this, a uniformity of the film thickness of the adhesive layer 40 can be determined, and a location where the film thickness of the adhesive layer 40 is not uniform can be positioned. The method for bonding detection is simple in design idea and easy to operate, and can be used to determine an effect of the bonding between the growth substrate 10 and the transient substrate 30.

Optionally, the apparatus for bonding detection further includes an auxiliary substrate 60, where the first electrode layer 51 and the first polarizer 91 are disposed on two opposite surfaces of the auxiliary substrate 60. The auxiliary substrate 60 is provided to provide a good support, which can increase a structural intensity, so that the first electrode layer 51, the first polarizer 91, and the liquid crystal component 70 have sufficient stability and reliability.

Optionally, the liquid crystal component 70 includes a first alignment film 71, a second alignment film 72, and the liquid crystal 73, where the first alignment film 71 is connected with the first electrode layer 51, the second alignment film 72 is connected with the growth substrate 10, and the liquid crystal 73 is disposed between the first alignment film 71 and the second alignment film 72. Structures of the first alignment film 71, the second alignment film 72, and the liquid crystal 73 are provided, so that a polarization direction of the polarized light can be adjusted, to select and filter a light passing through the liquid crystal component 70, which will not affect passing of normal lights while avoiding interference of external stray lights.

Optionally, the liquid crystal 73 has a thickness ranging from 2 μm to 4 μm. Specifically, the thickness of the liquid crystal 73 may be 2 μm, 3 μm, 4 μm, etc. Such thickness of the liquid crystal 73 is set, which can satisfy requirements for light selection and filtering of the liquid crystal component 70.

Optionally, the first electrode layer 51 and the second electrode layer 52 electrified by the power supply have opposite electrical polarities.

Optionally, the light detector is further configured to: measure a light-exiting intensity of the light exited, establish a database of a correspondence between thicknesses of the adhesive layer 40 and light-exiting intensities of the light by measuring a light-exiting intensity when the adhesive layer 40 has a preset thickness, and search for the thickness of the adhesive layer 40 in the database according to the light-exiting intensity of the light exited measured by the light detector.

Based on the same inventive concept, the disclosure further provides a method for thickness and uniformity detection. As illustrated in FIG. 7, the method for thickness and uniformity detection includes the following. A liquid crystal component 70 is disposed on one side of a portion 100 to-be-detected. A first electrode layer 51 is disposed on one side of the liquid crystal component 70 away from the portion to-be-detected, and a first polarizer 91 is disposed on one side of the first electrode layer 51 away from the liquid crystal component 70. A second electrode layer 52 is disposed on one side of the portion to-be-detected away from the liquid crystal component 70, and a second polarizer 92 is disposed on one side of the second electrode layer 52 away from the portion to-be-detected, where the second polarizer 92 has a polarization direction orthogonal to the first polarizer 91. The first polarizer 91 is irradiated with a uniform light, where the light is exited in a direction of the second polarizer 92. The first electrode layer 51 and the second electrode layer 52 are electrified to deflect a liquid crystal 73 of the liquid crystal component 70. The light exited from one side of the second polarizer 92 is received to detect a thickness and a uniformity of the portion to-be-detected.

In the implementation, the method of the disclosure is further applicable to detect uniformities of thicknesses of other parts to-be-detected besides to detect a uniformity of a thickness of a film layer. Specifically, the portion to-be-detected may be various plates, film layers, etc., which is not specifically limited herein. For specific detection principles, reference can be made to the foregoing implementations, which will not be repeated herein.

In an implementation, the portion 100 to-be-detected is embodied as the adhesive layer 40 in FIG. 5 and FIG. 6.

In these implementations, for relevant characteristics (e.g., specific structures, relevant connection relations, electrical polarities, etc.) of the first electrode layer 51, the second electrode layer 52, the first polarizer 91, and the second polarizer 92, reference can be made to the foregoing implementations, which will not be repeated herein. Besides the characteristics involved in these implementations, other characteristics in the foregoing implementations can also be added, and in combination with the illustration in the foregoing implementations, it is only necessary to set the other characteristics adaptively according to these implementations, which will not be repeated herein.

According to the method for thickness and uniformity detection of the implementation, by electrifying the first electrode layer 51 and the second electrode layer 52, a polarized light passing through the first polarizer 91 is exited from the second polarizer 92 under action of deflection of the liquid crystal 73 of the liquid crystal component 70. Since a voltage distribution is affected by structures between the first electrode layer 51 and the second electrode layer 52, different deflection of the liquid crystal 73 of the liquid crystal component 70 may occur, and thus the light exited has different transmittances and different light intensities. When the portion to-be-detected has a uniform film thickness, the light exited has regular light intensities; conversely, when the portion to-be-detected has a non-uniform film thickness, the light exited has a sudden-change light intensity(s) besides regular light intensities. Based on this, a uniformity of the film thickness of the portion to-be-detected can be determined, and a location where the film thickness of the portion to-be-detected is not uniform can be positioned. The method for thickness and uniformity detection is simple in design idea and easy to operate.

Referring to FIG. 5 and FIG. 6, based on the same inventive concept, the disclosure further provides an apparatus for thickness and uniformity detection. The apparatus for thickness and uniformity detection includes a liquid crystal component 70, a first electrode layer 51, a first polarizer 91, a second electrode layer 52, and a second polarizer 92. The liquid crystal component 70 is disposed on one side of a portion to-be-detected. The first electrode layer 51 is disposed on one side of the liquid crystal component 70 away from the portion to-be-detected, and the first polarizer 91 is disposed on one side of the first electrode layer 51 away from the liquid crystal component 70. The second electrode layer 52 is disposed on one side of the portion to-be-detected away from the liquid crystal component 70, and the second polarizer 92 is disposed on one side of the second electrode layer 52 away from the portion to-be-detected, where the second polarizer 92 has a polarization direction orthogonal to the first polarizer 91. The apparatus for thickness and uniformity detection further includes a light source, a power supply, and a light detector. The light source is configured to irradiate the first polarizer 91 with a uniform light, where the light is exited in a direction of the second polarizer 92. The power supply is configured to electrify the first electrode layer 51 and the second electrode layer 52 to deflect a liquid crystal 73 of the liquid crystal component 70. The light detector is configured to receive the light exited from one side of the second polarizer 92 to detect a thickness and a uniformity of the portion to-be-detected.

According to the apparatus for thickness and uniformity detection, by electrifying the first electrode layer 51 and the second electrode layer 52, a polarized light passing through the first polarizer 91 is exited from the second polarizer 92 under action of deflection of the liquid crystal 73 of the liquid crystal component 70. Since a voltage distribution is affected by structures between the first electrode layer 51 and the second electrode layer 52, different deflection of the liquid crystal 73 of the liquid crystal component 70 may occur, and thus the light exited has different transmittances and different light intensities. When the portion to-be-detected has a uniform film thickness, the light exited has regular light intensities; conversely, when the portion to-be-detected has a non-uniform film thickness, the light exited has a sudden-change light intensity(s) besides regular light intensities. Based on this, a uniformity of the film thickness of the portion to-be-detected can be determined, and a location where the film thickness of the portion to-be-detected is not uniform can be positioned. The method for thickness and uniformity detection is simple in design idea and easy to operate.

It is to be understood that the disclosure is not to be limited to the disclosed implementations. Those of ordinary skill in the art can make improvements or changes based on the above description, and all these improvements and changes should fall within the protection scope of the appended claims of this disclosure.

What is claimed is:

1. A method for bonding detection, applicable to detect bonding of a growth substrate and a transient substrate, a light-emitting element on the growth substrate being connected with an adhesive layer on the transient substrate, the method for bonding detection comprising:
disposing a liquid crystal component on one side of the growth substrate away from the light-emitting element;
disposing a first electrode layer on one side of the liquid crystal component away from the growth substrate, and disposing a first polarizer on one side of the first electrode layer away from the liquid crystal component;
disposing a second electrode layer on one side of the transient substrate away from the adhesive layer, and disposing a second polarizer on one side of the second electrode layer away from the transient substrate, the second polarizer having a polarization direction orthogonal to the first polarizer;
irradiating the first polarizer with a uniform light, the light being exited in the polarization direction of the second polarizer;
electrifying the first electrode layer and the second electrode layer to deflect a liquid crystal of the liquid crystal component; and
receiving the light exited from one side of the second polarizer to detect a thickness and a uniformity of the adhesive layer.

2. The method for bonding detection of claim 1, further comprising:
disposing the first electrode layer and the first polarizer on two opposite surfaces of an auxiliary substrate.

3. The method for bonding detection of claim 1, wherein the liquid crystal component comprises a first alignment film, a second alignment film, and the liquid crystal, wherein the first alignment film is connected with the first electrode layer, the second alignment film is connected with the growth substrate, and the liquid crystal is disposed between the first alignment film and the second alignment film.

4. The method for bonding detection of claim 1, wherein the liquid crystal has a thickness ranging from 2 μm to 4 μm.

5. The method for bonding detection of claim 1, wherein the first electrode layer and the second electrode layer electrified have opposite electrical polarities.

6. The method for bonding detection of claim 1, further comprising:
establishing a database of a correspondence between thicknesses of the adhesive layer and light-exiting intensities by measuring a light-exiting intensity when the adhesive layer has a preset thickness; and
wherein detect the thickness of the adhesive layer comprises:
measuring a light-exiting intensity of the light exited; and
searching for the thickness of the adhesive layer in the database according to the light-exiting intensity of the light exited.

7. The method for bonding detection of claim 1, wherein detect the uniformity of the adhesive layer comprises:
measuring the light exited to obtain a whole light-intensity distribution;
searching for a sudden-change light intensity in the whole light-intensity distribution; and
determining the uniformity of the adhesive layer based on the sudden-change light intensity searched.

8. An apparatus for bonding detection, applicable to detect bonding of a growth substrate and a transient substrate, a light-emitting element on the growth substrate being connected with an adhesive layer on the transient substrate, the apparatus for bonding detection comprising:
a liquid crystal component, a first electrode layer, a first polarizer, a second electrode layer, and a second polarizer, wherein the liquid crystal component is disposed on one side of the growth substrate away from the light-emitting element, the first electrode layer is disposed on one side of the liquid crystal component away from the growth substrate, the first polarizer is disposed on one side of the first electrode layer away from the liquid crystal component, the second electrode layer is disposed on one side of the transient substrate away from the adhesive layer, the second polarizer is disposed on one side of the second electrode layer away from the transient substrate, and the second polarizer has a polarization direction orthogonal to the first polarizer; and
a light source, a power supply, and a light detector, wherein the light source is configured to irradiate the first polarizer with a uniform light, the light is exited in the polarization direction of the second polarizer, the power supply is configured to electrify the first electrode layer and the second electrode layer to deflect a liquid crystal of the liquid crystal component, and the light detector is configured to receive the light exited from one side of the second polarizer to detect a thickness and a uniformity of the adhesive layer.

9. The apparatus for bonding detection of claim 8, further comprising an auxiliary substrate, wherein the first electrode layer and the first polarizer are disposed on two opposite surfaces of the auxiliary substrate.

10. The apparatus for bonding detection of claim 8, wherein the liquid crystal component comprises a first alignment film, a second alignment film, and the liquid crystal, wherein the first alignment film is connected with the first electrode layer, the second alignment film is connected with the growth substrate, and the liquid crystal is disposed between the first alignment film and the second alignment film.

11. The apparatus for bonding detection of claim 8, wherein the liquid crystal has a thickness ranging from 2 μm to 4 μm.

12. The apparatus for bonding detection of claim 8, wherein the first electrode layer and the second electrode layer electrified by the power supply have opposite electrical polarities.

13. The apparatus for bonding detection of claim 8, wherein the light detector is further configured to measure a light-exiting intensity of the light exited, establish a database of a correspondence between thicknesses of the adhesive layer and light-exiting intensities by measuring a light-exiting intensity when the adhesive layer has a preset thickness, and search for the thickness of the adhesive layer in the database according to the light-exiting intensity of the light exited measured by the light detector.

14. The apparatus for bonding detection of claim 8, wherein the light detector is further configured to measure the light exited to obtain a whole light-intensity distribution; search for a sudden-change light intensity in the whole light-intensity distribution; and determine the uniformity of the adhesive layer based on the sudden-change light intensity searched.

15. A method for thickness and uniformity detection, comprising:
disposing a liquid crystal component on one side of a portion which is to be detected;
disposing a first electrode layer on one side of the liquid crystal component away from the portion, and disposing a first polarizer on one side of the first electrode layer away from the liquid crystal component;
disposing a second electrode layer on one side of the portion away from the liquid crystal component, and disposing a second polarizer on one side of the second electrode layer away from the portion, the second polarizer having a polarization direction orthogonal to the first polarizer;
irradiating the first polarizer with a uniform light, the light being exited in the polarization direction of the second polarizer;
electrifying the first electrode layer and the second electrode layer to deflect a liquid crystal of the liquid crystal component; and
receiving the light exited from one side of the second polarizer to detect a thickness and a uniformity of the portion.

16. The method for thickness and uniformity detection of claim 15, further comprising:
establishing a database of a correspondence between thicknesses of the portion and light-exiting intensities by measuring a light-exiting intensity when the portion has a preset thickness; and
wherein detect the thickness of the portion comprises:
measuring a light-exiting intensity of the light exited; and
searching for the thickness of the portion in the database according to the light-exiting intensity of the light exited.

17. The method for thickness and uniformity detection of claim 15, wherein detect the uniformity of the portion comprises:
measuring the light exited to obtain a whole light-intensity distribution;
searching for a sudden-change light intensity in the whole light-intensity distribution; and
determining the uniformity of the portion based on the sudden-change light intensity searched.

18. The method for thickness and uniformity detection of claim 15, wherein the liquid crystal has a thickness ranging from 2 μm to 4 μm.

19. The method for thickness and uniformity detection of claim 15, wherein the first electrode layer and the second electrode layer electrified have opposite electrical polarities.

20. The method for thickness and uniformity detection of claim 15, wherein the liquid crystal component comprises a first alignment film, a second alignment film, and the liquid crystal, wherein the first alignment film is connected with the first electrode layer, the second alignment film is connected with the portion, and the liquid crystal is disposed between the first alignment film and the second alignment film.
